(19) United States
(12) Patent Application Publication
(10) Pub. No.: US 2025/0081824 A1
(43) Pub. Date: Mar. 6, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jiajia SUN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/557,952

(22) PCT Filed: Jun. 30, 2023
(86) PCT No.: PCT/CN2023/104659

§ 371 Date: Oct. 29, 2023

(30) Foreign Application Priority Data
Sep. 21, 2022 (CN) 202211151613.6

(51) Int. Cl. H10K 59/80

(52) U.S. Cl. CPC H10K 59/879; H10K 59/873

(57) ABSTRACT

A display panel and a display device are provided. The display panel includes a substrate, a light-emitting layer, a first refractive layer including openings and first grooves and a second refractive layer filling the openings. A refractive index of the second refractive layer is greater than a refractive index of the first refractive layer. The first groove comprises solid units spaced apart and interconnected microgrooves, each of the microgrooves is disposed between every adjacent two of the solid units, and the second refractive layer fills the microgrooves and covers the solid units.

### TECHNICAL FIELD

The present application relates to the field of display technologies, and more particularly, to a display panel and a display device.

### BACKGROUND

An Organic light-emitting diode (OLED) device has advantages of light weight, wide viewing angle, high light-emitting efficiency and the like, compared with a conventional Liquid crystal display (LCD).

In the prior art, by geometrical optics, a Micro-lens pattern (MLP) structure is provided in an OLED screen body, and relatively divergent light emitted from the OLED screen body is converged to directly above the screen body by the MLP structure, so as to improve efficiency of the OLED screen body. However, the above-described MLP structure generally requires a planarization layer formed by an Ink jet printing (IJP) to planarize it to facilitate subsequent processing. At the same time, in order to prevent the overflow of the ink in the IJP process, it is also necessary to provide a blocking structure, such as a groove or a retaining wall, in advance in the peripheral area of the screen, so as to prevent the overflow of the ink. However, the ink is not flowed to an edge of the blocking structure which is adjacent to the display area, so that there is stress concentration at this edge, and the display panel is at a risk of breaking a metal line when being bent.

### SUMMARY

An embodiment of the present application provides a display panel to solve the technical problem that when all grooves in a MLP structure are hollowed out, a stress concentration occurs at an edge at which ink cannot flow when a planarization layer is formed by IJP, and there is a risk of breaking a metal wire in the conventional display panel and the conventional display device.

To solve the above problems, the present application provides the following technical solutions.

The present application provides a display device including a display area and a non-display area located on at least one side of the display area;
the display panel further comprising:
a substrate;
a light-emitting layer disposed on one side of the substrate, the light-emitting layer comprising a plurality of light-emitting portions disposed in the display area;
a first refractive layer disposed on a side of the light-emitting layer which is away from the substrate, the first refractive layer comprising a plurality of openings arranged in array in the display area and corresponding to the plurality of light-emitting portions, and a first groove arranged in the non-display area; and
a second refractive layer disposed on a side of the first refractive layer which is away from the substrate, the second refractive layer filling the plurality of openings, and a refractive index of the second refractive layer being greater than a refractive index of the first refractive layer;
in which the first groove comprises a plurality of solid units spaced apart and a plurality of interconnected microgrooves, each of the microgrooves is disposed between every adjacent two of the solid units, and the second refractive layer fills the microgrooves and covers the solid units.

According to the display panel provided by the present application, the first groove includes a plurality of groups of arrangement arrays arranged in sequence in a direction away from the display area, each of the groups of arrangement arrays comprises ones of the solid units and ones of the microgrooves arranged in sequence, the ones of the solid units in the group of arrangement arrays and the ones of the solid units in an adjacent one of the groups of arrangement arrays are staggered with respect to each other, and the ones of the microgrooves in the group of arrangement arrays and the ones of the microgrooves in the adjacent one of the groups of arrangement arrays are staggered with respect to each other.

According to the display panel provided by the present application, in one column of the groups of arrangement arrays which is adjacent to the display area, sizes of ones, in the one column of the groups of arrangement arrays, of the microgrooves are gradually reduced in a direction from adjacent to the display area to away from the display area.

According to the display panel provided by the present application, areas of orthographic projections of ones, in different ones of the groups of arrangement arrays, of the solid units are on the substrate are gradually reduced in the direction away from the display area.

According to the display panel provided by the present application, a ratio of a distance between adjacent two of the solid units, which are each in a corresponding group of adjacent two of the groups of arrangement arrays, to a width of a bottom wall of the first groove is less than or equal to ⅛, and a ratio of a maximum dimension of each of the solid units to the width of the bottom wall of the first groove is less than or equal to ¼.

According to the display panel provided by the present application, the distance between the adjacent two of the solid units, which are each in the corresponding group of the adjacent two groups of arrangement arrays, is less than or equal to 5 microns, and the maximum size of each of the solid units is less than or equal to 10 microns.

According to the display panel provided by the present application, the groups of arrangement arrays comprise three or more groups of arrangement arrays.

According to the display panel provided by the present application, the first groove extends through the first refractive layer, and a depth of the first groove is equal to a depth of each of the microgrooves and a height of each of the solid units in a thickness direction of the display panel.

According to the display panel provided by the present application, the first refractive layer further comprises a second groove arranged within the non-display area, and the second groove is located on a side of the first groove which is away from the display area;
in which a boundary of the second refractive layer is located in the second groove or between the second groove and the first groove.

According to the display panel provided by the present application, in a thickness direction of the display panel, the microgrooves have same depths as the openings, and the first groove has a same depth as the second groove.

According to the display panel provided by the present application, the non-display area comprises a bending area and a bonding area located on a side of the bending area which is away from the display area, and the bonding area is bent to a back of the display area through the bending area; wherein the first groove and the second groove are disposed between the bending area and the display area.

According to the display panel provided by the present application, the display panel further comprises:
an encapsulation layer covering a side of the light-emitting layer which is away from the substrate; and
a touch control stack disposed on one side of the encapsulation layer which is away from the substrate, and the touch control stack comprises a first insulating layer, a first touch control metal layer, a second insulating layer, a second touch control metal layer, and the first refractive layer stacked in sequence, wherein the first touch control metal layer or the second touch control metal layer is provided with a touch control electrode.

According to the display panel provided by the present application, a surface of one side, which is away from the substrate, of each of the solid units is provided with a plurality of micro-solid units spaced apart and a plurality of interconnected sub-microgrooves, and each of the sub-microgrooves is provided between every adjacent two of the micro-solid units.

A display device provided by the present application including the above-mentioned display panel; the display panel including a display area and a non-display area located on at least one side of the display area;
the display panel further including:
a substrate;
a light-emitting layer disposed on one side of the substrate, the light-emitting layer comprising a plurality of light-emitting portions disposed in the display area;
a first refractive layer disposed on a side of the light-emitting layer which is away from the substrate, the first refractive layer comprising a plurality of openings arranged in array in the display area and corresponding to the plurality of light-emitting portions, and a first groove arranged in the non-display area; and
a second refractive layer disposed on a side of the first refractive layer which is away from the substrate, the second refractive layer filling the plurality of openings, and a refractive index of the second refractive layer being greater than a refractive index of the first refractive layer;
in which the first groove comprises a plurality of solid units spaced apart and a plurality of interconnected microgrooves, each of the microgrooves is disposed between every adjacent two of the solid units, and the second refractive layer fills the microgrooves and covers the solid units.

According to the display device provided by the present application, the first groove comprises a plurality of groups of arrangement arrays arranged in sequence in a direction away from the display area, each of the groups of arrangement arrays comprises ones of the solid units and ones of the microgrooves arranged in sequence, the ones of the solid units in the group of arrangement arrays and the ones of the solid units in an adjacent one of the groups of arrangement arrays are staggered with respect to each other, and the ones of the microgrooves in the group of arrangement arrays and the ones of the microgrooves in the adjacent one of the groups of arrangement arrays are staggered with respect to each other.

According to the display device provided by the present application, in one column of the groups of arrangement arrays which is adjacent to the display area, sizes of ones, in the one column of the groups of arrangement arrays, of the microgrooves are gradually reduced in a direction from adjacent to the display area to away from the display area.

According to the display device provided by the present application, areas of orthographic projections of ones, in different ones of the groups of arrangement arrays, of the solid units are on the substrate are gradually reduced in the direction away from the display area.

According to the display device provided by the present application, a ratio of a distance between adjacent two of the solid units, which are each in a corresponding group of adjacent two of the groups of arrangement arrays, to a width of a bottom wall of the first groove is less than or equal to ⅛, and a ratio of a maximum dimension of each of the solid units to the width of the bottom wall of the first groove is less than or equal to ¼.

According to the display device provided by the present application, the distance between the adjacent two of the solid units, which are each in the corresponding group of the adjacent two groups of arrangement arrays, is less than or equal to 5 microns, and the maximum size of each of the solid units is less than or equal to 10 microns.

According to the display device provided by the present application, the groups of arrangement arrays comprise three or more groups of arrangement arrays.

### BENEFICIAL EFFECT

Advantageous effects of the present application are as follows. According to the display panel and the display device provided in the present application, the display panel includes a substrate, a light-emitting layer, a first refractive layer and a second refractive layer. The first refractive layer includes a first groove arranged in a display area. A plurality of solid units spaced apart and a plurality of interconnected microgrooves are disposed in the first groove. Each microgroove is disposed between every adjacent two solid units, and the second refractive layer fills the microgrooves and covers the solid units. When the second refractive layer is formed by IJP, by capillary action of the microgrooves, ink can flow to the edge of the first groove which is close to the display area through channels formed by the plurality of interconnected microgrooves. In this way, it can avoid a stress concentration phenomenon in this edge due to the fact that the edge position is not flowed by the ink, thereby reducing the risk of metal line breakage when the display panel is bent, and prolonging the service life of the display panel.

### BRIEF DESCRIPTION OF THE DRAWINGS

In order that the technical solution in the embodiments of the present application may be explained more clearly, reference will now be made briefly to the accompanying drawings required for the description of the embodiments. It will be apparent that the accompanying drawings in the following description are merely some of the embodiments of the present application, and other drawings may be made to those skilled in the art without involving any inventive effort.

FIG. 1 is a schematic plan view of a display panel according to an embodiment of the present application;

FIG. 2 is a schematic sectional view taken along line A-A in FIG. 1;

FIG. 3 is a schematic view of a partially enlarged structure at position B in FIG. 1;

FIG. 4 is a schematic view of a partially enlarged structure at position C in FIG. 2;

FIG. 5 is another schematic sectional view taken along line A-A in FIG. 1;

FIG. 6 is a schematic view of a partially enlarged structure at position D in FIG. 5; and

FIG. 7 is a flowchart of a method for manufacturing a display panel according to an embodiment of the present application;

FIGS. 8A-8D are schematic flow diagrams of a method for manufacturing a display panel according to an embodiment of the present application.

### DETAILED DESCRIPTION

In the following, the technical solutions in the embodiments of the present application will be clearly and completely described in connection with the accompanying drawings in the embodiments of the present application. It will be apparent that the described embodiments are merely some of the embodiments of the present application, rather than all the embodiments. Based on the embodiments in the present application, all other embodiments obtained by a person skilled in the art without involving any inventive effort are within the scope of the present application. Furthermore, it is to be understood that the specific embodiments described herein are for purposes of illustration and explanation only and are not intended to limit the application. In the present application, if not stated to the contrary, the positional terms used such as “upper” and “lower” usually refer to the upper and lower positions with respect to the device in actual use or working conditions, specifically to the direction in the drawings; while “inside” and “outside” refer to the outline of the device.

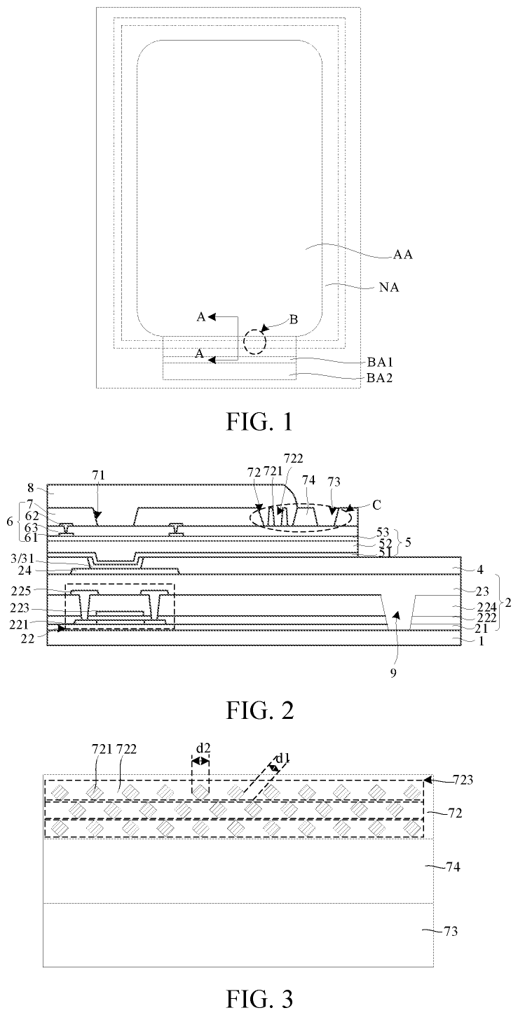

Referring to FIGS. 1 and 2, an embodiment of the present application provides a display panel including a display area AA and a non-display area NA located on at least one side of the display area AA.

The display panel further includes a substrate 1, a light-emitting layer 3, a first refractive layer 7, and a second refractive layer 8. The light-emitting layer 3 is provided on one side of the substrate 1, and includes a plurality of light-emitting portions 31 provided in the display area AA. The first refractive layer 7 includes a plurality of openings 71 arranged in array in the display area AA and corresponding to the plurality of light-emitting portions 31, and a first groove 72 arranged in the non-display area NA. The second refractive layer 8 is disposed on the side of the first refractive layer 7 away from the substrate 1 and fills the plurality of openings 71. The refractive index of the second refractive layer 8 is greater than the refractive index of the first refractive layer 7.

The first groove 72 includes a plurality of spaced-apart solid units 721 and a plurality of interconnected micro-trenches 722 each disposed between every adjacent two solid units 721. The second refractive layer 8 fills the micro-trenches 722 and covers the solid units 721.

As described in the background art, in an implementation application, the second refractive layer 8 is formed by an IJP process, and in order to prevent ink from overflowing to the outside of the display panel, the first groove 72 is usually provided in the non-display area NA. However, since, at the time of IP, the ink does not flow to an edge (on the left side of the first groove 72 in FIG. 2) of the blocking structure which is adjacent to the display area AA, there is stress concentration at this edge. So, in order to reduce the frame of the display panel, the display panel needs to be bent in the non-display area NA, so that there is a risk of metal line breakage at this edge.

It will be appreciated that embodiments of the present application provide a plurality of spaced-apart solid units 721 and a plurality of interconnected microgrooves 722 each disposed between every adjacent two solid units 721. The second refraction layer 8 fills the microgrooves 722 and covers the solid units 721. The plurality of microgrooves 722 form channels for ink to flow. When the second refraction layer 8 is formed by IJP, the ink can flow through the channels formed by the plurality of interconnected microgrooves 722 to the edge of the first groove 72 which is adjacent to the display area AA by capillary action of the microgrooves 722. So, a stress concentration phenomenon in this edge is avoided, the risk of metal line breakage of the display panel at the time of bending is reduced, and the service life of the display panel is improved.

It should be noted that the display area AA refers to an area used for the light-emitting display in the display panel, and the non-display area NA refers to an area around the display area AA. In the present embodiment, the display area AA is surrounded by the non-display area NA. It should be noted that this should not be construed as a limitation on the positions of both the display area AA and the non-display area NA, and the non-display area NA may be present only on outside one side or any few sides of the display area AA.

The display panel further includes a driving circuit layer 2, a pixel definition layer 4, an anode 24, a cathode (not shown), an encapsulation layer 5, and a touch control stack 6. The thin film transistor array layer 22 is disposed between the substrate 1 and the light-emitting layer 3. The pixel definition layer 4 is disposed on the thin film transistor array layer 22. The anode 24 is disposed on the pixel definition layer 4. The pixel definition layer 4 includes a plurality of pixel openings 71 arranged in array. At least part of the anode 24 is exposed out of the pixel opening 71. The light-emitting layer 3 is disposed in the pixel openings 71. The cathode is disposed on the pixel definition layer 4 and the light-emitting layer 3. The encapsulation layer 5 is disposed on the cathode to encapsulate the light-emitting portion 31. The touch control stack 6 is disposed on the encapsulation layer 5, and the first refractive layer 7 is disposed on the touch control stack 6.

The driving circuit layer 2 further includes a buffer layer 21 provided between the thin film transistor array layer 22 and the substrate 1, and a planarization layer 23 covering the thin film transistor array layer 22. The pixel definition layer 4 provided on the thin film transistor array layer 22.

Here, the thin film transistor array layer 22 further includes a thin film transistor device provided on the buffer layer 21. The thin film transistor device may be an etch-blocking type, a back-channel etching type, or a structure such as a bottom-gate thin film transistor device or a top-gate thin film transistor device divided according to the positions of the gate 223 and the active layer 221, which is not specifically limited.

For example, the thin film transistor device shown in FIG. 2 is a top gate type thin film transistor device, which may include an active layer 221 disposed on the buffer layer 21, a gate insulating layer 222 disposed on the active layer 221, a gate 223 disposed on the gate insulating layer 222, an interlayer dielectric layer 224 disposed on the gate 223, and a source-drain metal layer 225 disposed on the interlayer dielectric layer 224. The source-drain metal layer 225 includes a source and a drain. The source and the drain are electrically connected to the active layer 221 by vias extending through both the interlayer dielectric layer 224 and the gate insulating layer 222.

The encapsulation layer 5 includes a first inorganic encapsulation layer 51, an organic encapsulation layer 52, and a second inorganic encapsulation layer 53, which are sequentially laminated on the pixel definition layer 4. The touch control stack 6 includes a first insulating layer, a first touch control metal layer 61, a second insulating layer 63, a second touch control metal layer 62, and the first refractive layer 7 stacked in sequence. A touch control electrode is provided in the first touch control metal layer 61 or the second touch control metal layer 62. In the embodiment of the present application, the first refractive layer 7 is a part of the touch control stack 6, that is, the first refractive layer 7 is reused as an insulating layer in the touch control stack 6. Therefore, an additional insulating layer covering the second touch control metal layer 62 does not need to be provided between the first refractive layer 7 and the second touch control metal layer 62, so that the overall thickness of the display panel can be reduced. The touch control stack 6 may be Direct cell touch (DOT). The touch control stack 6 provided in the embodiment of the present application may be of a mutual-capacitance type or a self-capacitance type, but is not limited thereto. Specifically, the type and the structure of the touch control stack 6 may be selected according to actual requirements.

The first refractive layer 7 is a low refractive index layer, and the second refractive layer 8 is a high refractive layer. The low refractive layer is located at least in the display area AA, and the high refractive layer extends from the display area AA to the non-display area NA. The second refractive layer 8 fills a plurality of the openings 71 of the first refractive layer 7 to form a plurality of microlens units. And, the light emitted by the light emitting portions 31 is converged at the boundary of the first refractive layer 7 and the second refractive layer 8 by means of the refractive index difference between the first refractive layer 7 and the second refractive layer 8, so as to serve as a light condensing effect. In this way, the light emitting effect of the light emitting portions 31 corresponding thereto is improved, so as to improve the light emitting efficiency of the display panel. In addition, the light emitted by the light emitting portions 31 can be emitted as far as possible from the front direction to improve the viewing angle of the emitted light.

Specifically, the refractive index of the first refractive layer 7 may be 1.4 to 1.6, and the material of the first refractive layer 7 may include a light-transmitting organic material having a low refractive index, such as an Poly(acrylic resin), a polyimide resin, a polyamide resin, and/or 8-Hydroxyquinoline aluminum salt. The refractive index of the second refractive layer 8 may be 1.61 to 1.8, and the material of the second refractive layer 8 may include a light-transmitting organic material having a high refractive index, such as poly(3,4-ethylenedioxythiophene) (referred briefly to as PEDOT), 4,4′-bis[N-(3-methylphenyl)-N-phenylamino]biphenyl (referred briefly to as TPD) 4,4′,4″-tris[(3-methylphenyl)phenylamino]triphenylamine (referred briefly to as m-MTDATA), 1,3,5-tris[N,N-bis(2-methylphenyl)-amino]-benzene (referred briefly to as o-MTDAB), 1,3,5-tris[N,N-bis(3-methylphenyl)-amino]-benzene (referred briefly to as m-MTDAB), 1,3,5-tris[N,N-bis(4-methylphenyl)-amino]-benzene (referred briefly to as p-MTDAB), 4,4′-bis[N,N-bis(3-methylphenyl)-amino]-diphenylmethane (referred briefly to as BPPM), 4,4′-N,N′-dicarbazol-biphenyl (referred briefly to as CBP), 4′4′,4″-tris(carbazol-9-yl)-triphenylamine (referred briefly to as TCTA), 2,2′,2″-(1,3,5-phenylene)tris-[1-phenyl-1H-benzimidazole](referred briefly to as TPBI), and/or 3-(4-biphenyl)-4-phenyl-5-t-butylphenyl-1,2,4-triazole (referred briefly to as TAZ).

The second refractive layer 8 may also be doped with nanoparticles such as ZrO₂/TiO₂ to adjust the direction of refraction of the light, so as to increase the emitting rate of the light emitting portions 31.

The first refractive layer 7 further includes a second groove 73 arranged in the non-display area NA. The second groove 73 is located on the side of the first groove 72 away from the display area AA. The second refractive layer 8 fills the second groove 73, or the boundary of the second refractive layer 8 terminates in the second groove 73 or between the second groove 73 and the first groove 72.

A portion of the first refractive layer 7 between a side wall of the first groove 72 and a side wall of the second groove 73 forms a retaining wall 74. The first groove 72 and the second groove 73 both serve to prevent overflow of ink, and the plurality of grooves can more accurately control formation of the ink flow, compared with providing only one groove. The first groove 72 provided close to the display area AA can serve as a main groove for controlling overflow of the second refractive layer 8, and the second groove 73 can serve as an auxiliary groove for preventing overflow of the second refractive layer 8 above the first groove 72. The first groove 72 and the second groove 73 cooperate to ensure that ink does not overflow out of the non-display area NA.

Further, the non-display area NA includes a bending area BA1 and a bonding area BA2 located on the side of the bending area BA1 away from the display area AA. The bonding area BA2 is bent to the back of the display area AA through the bending area BA1. So, a width of the frame can be reduced, thereby realizing narrow frame display. The first groove 72 and the second groove 73 are disposed between the bending region BA1 and the display region AA.

The bending region BA1 is provided with a third groove 9, and the third groove 9 extends through the interlayer dielectric layer 224, the gate insulating layer 222, and the buffer layer 21. The planarization layer 23 fills the third groove 9 to reduce the thickness of the display panel in the bending region BA1, thereby reducing the bending stress of the display panel. So, the display panel has better bending characteristics.

Referring to FIGS. 3 and 4, the first groove 72 includes a plurality of groups of arrangement arrays 723 arranged in sequence in a direction away from the display area AA. Each group of the arrangement arrays 723 includes multiple solid units 721 and multiple microgrooves 722 arranged in sequence. The solid units 721 in two adjacent groups of the arrangement arrays 723 are arranged staggered with respect to each other, and the microgrooves 722 in two adjacent groups of the arrangement arrays 723 are arranged staggered with respect to each other, so that the formed channels are arranged in a zigzag manner. In this way, the flow paths of the ink are zigzag to extend the flow paths of the ink, compared with the flow paths in a straight shape. So, the length of the flow path of the ink can be increased, the flow velocity of the ink can be reduced, and the final flow cutoff position of the ink can be more easily located on one side of the retaining wall 74 which is adjacent to the display area AA. That is, the boundary of the second refractive layer 8 is terminated at the side of the retaining wall 74 which is close to the display area AA, thereby reducing the risk of overflow of the second refractive layer 8 during the IJP stage, particularly in the case where the display panel is designed with a narrow frame.

Specifically, a width of the first groove 72 is greater than or equal to 40 μm, a width of the second groove 73 is greater than or equal to 40 μm, and a spacing between the first groove 72 and the second groove 73 is greater than or equal to 40 μm.

In a column of the arrangement arrays 723, which is adjacent to the display area AA, of the plurality of groups of the arrangement arrays 723, the sizes of these microgrooves 722 gradually decreases in a direction from close to the display area AA to away from the display area AA. That is, the sizes of ones of the microgrooves 722 which are close to the display area AA are larger than the sizes of ones of the microgrooves 722 which are away from the display area AA. The reason for this is that: since the microgrooves 722, which are located on the front most side adjacent to the display area AA, of the arrangement arrays 723 can play a certain drainage function, the ink can easily flow into the first groove 72. Furthermore, the microgrooves 722, which are located on the rear most side away from the display area AA, of the arrangement arrays 723 are staggered with respect to each other. In this way, these microgrooves 722 can play a current-limiting role in blocking the flow of the flowable ink, thereby reducing the flow speed of the ink, and further reducing the risk of overflow of the second refractive layer 8 in the IJP stage. Further, since the arrangement arrays 723 have a capillary effect, ink easily flows along the flow paths from the larger-size microgrooves 722 to the side of the first groove 72 which is close to the display area AA. That is, the ink easily flows to the first refractive layer 7 not covered by ink.

In an embodiment of the present application, the ratio of the distance d1 between adjacent two solid units 721, which are each in a corresponding one of two adjacent groups of arrangement arrays 723, to a width of a bottom wall of the first groove 72 is less than or equal to ⅛, and a ratio of a maximum dimension d2 of each of the solid units 721 to a width of the bottom wall of the first groove 72 is less than or equal to ¼.

Specifically, the distance d1 between two adjacent solid units 721 which are each in a corresponding one of two adjacent groups of the arrangement arrays 723 is less than or equal to 5 microns, and the maximum dimension d2 of each of the solid units 721 is less than or equal to 10 microns.

In the embodiment of the present application, in order to ensure capillary effect, the number of the groups of the arrangement arrays 723 is greater than or equal to 3. It should be further noted that the number of the groups of the arrangement arrays 723 may be selected according to its own requirements, so long as it is ensured that the microgrooves 722 in two adjacent groups of the arrangement arrays 723 are staggered with respect to each other.

The number of the solid units 721 in each group of the arrangement arrays 723 is greater than or equal to 3, that is, the solid units 721 are arranged to be at least three rows and at least three columns to ensure capillary effect.

Alternatively, the shape of the orthographic projection of the solid unit 721 on the substrate 1 includes one of a square shape, a rectangle shape, a diamond shape, a circle shape, and an ellipse shape. In an embodiment of the present application, the shape of the orthographic projection of the solid unit 721 on the substrate 1 is the diamond shape.

The shape of the microgroove 722 in the cross-sectional direction of the display panel may be an inverted trapezoid, which is due to the manufacturing process. The microgrooves 722 and the solid units 721 are simultaneously formed by a yellow light processing process. The further the openings 71 from the light-emitting portion 31, the narrower the openings 71 is, and the shallower the etching is. Therefore, the gradient of the microgroove 722 is formed.

For multiple solid units 721 in the same group of the arrangement arrays 723, the sizes of the multiple solid units 721 may be the same or different. For multiple solid units 721 in different groups of the arrangement arrays 723, the sizes of the multiple solid units 721 may be the same or different. It should be noted that, in the embodiment of the present application, the areas of the orthographic projections of the solid units 721 in different groups of the arrangement arrays 723 on the substrate 1 are gradually reduced in the direction away from the display area AA. This is because a part of the first refractive layer 7 which is not covered by the second refractive layer 8 in the prior art depends mainly on ones, which are arranged close to the display area AA, of the plurality of groups of the arrangement arrays. In this way, the areas of the orthographic projections of the solid units 721, which are close to the display area AA, of the arrangement arrays 723 are larger on the substrate 1, and the areas of the orthographic projections of the solid units 721, which are away from the display area AA, of the arrangement arrays 723 are smaller on the substrate 1. That is, the sizes of the microgrooves 722, which are close to the display area AA, of the arrangement arrays 723 can be made larger, and the sizes of the microgrooves 722, which are away from the display area AA, of the arrangement arrays 723 are made smaller. The ink in the flow paths is relatively easy to flow into these positions to cover the first refractive layer 7.

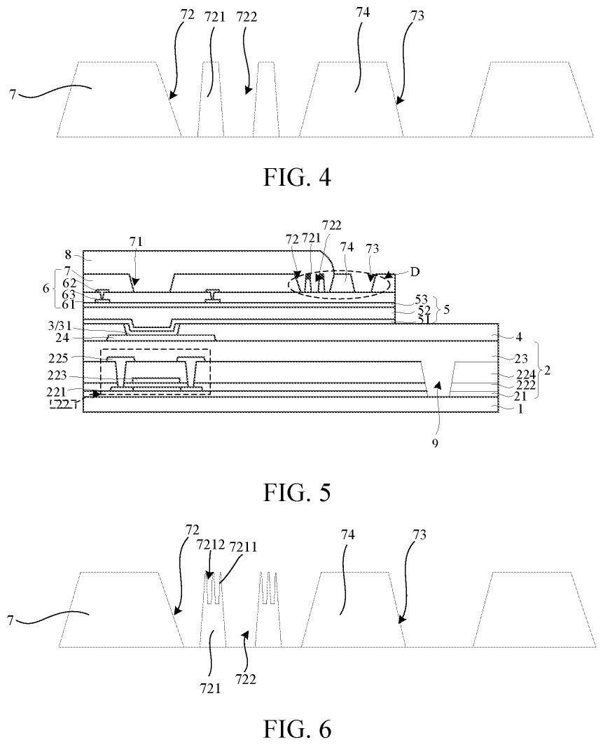

Further, referring to FIGS. 5 and 6, a surface of a side, which is away from the substrate 1, of the solid unit 721 is provided with a plurality of spaced-apart micro-solid units 7211 and a plurality of interconnected sub-microgrooves 7212 each disposed between every two adjacent micro-solid units 7211. The micro-solid units 7211 and the sub-microgrooves 7212 also have a capillary function to supplement the a part of the first refractive layer 7 which is not covered by the second refractive layer 8 in the prior art. The principle thereof can be referred to the above principle of capillary function of the solid unit 721 and the microgrooves 722, which will not be described in detail herein.

The first groove 72 may extend through the first refractive layer 7 or may not extend completely through the first refractive layer 7. In the present embodiment, the first groove 72 extends through the first refractive layer 7, so that the effect of the first groove 72 blocking the ink is better. Of course, the second groove 73 may also extend through the second refractive layer 8 or not completely through the first refractive layer 7.

In the thickness direction of the display panel, the depth of the first groove 72 is equal to the depth of the microgroove 722 and the height of the solid unit 721. That is, in the embodiment of the present application, the microgrooves 722, the solid units 721, and the first groove 72 are all formed by the same yellow light process. Further, the microgrooves 722, the solid units 721, the first groove 72, and the second groove 73 are all formed by the same yellow light process.

Further, in the thickness direction of the display panel, the depths of the microgrooves 722 are the same as the depths of the openings 71, and the depths of the first groove 72 are the same as the depths of the second groove 73. That is, the microgrooves 722, the openings 71, the first groove 72, and the second groove 73 are all formed by the same yellow light process.

In the present embodiment, the material of the solid unit 721 is the same as the material of the first refractive layer 7, and the solid unit 721 is convex.

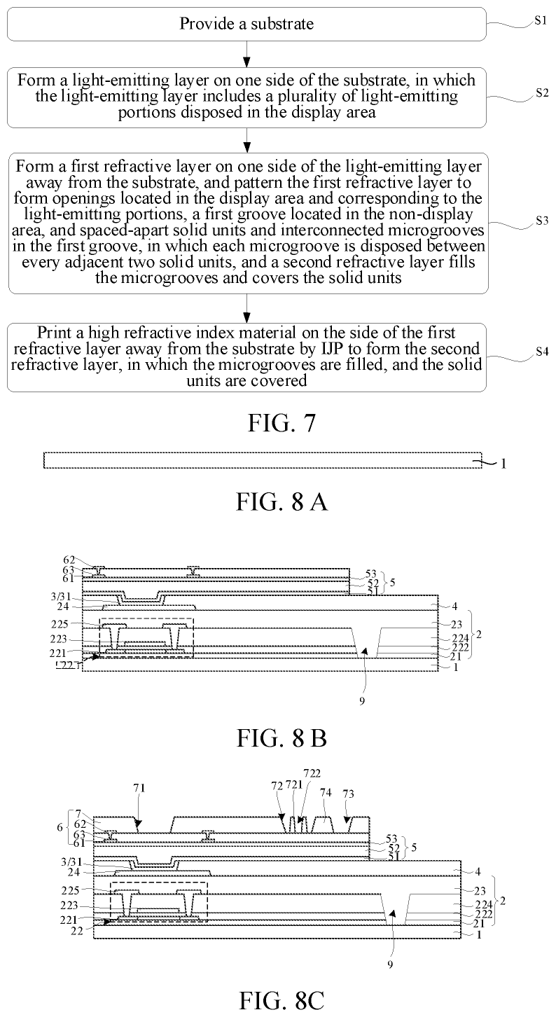

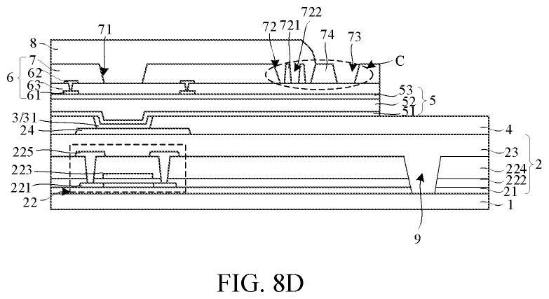

Referring to FIGS. 7 and 8A-8D, an embodiment of the present application further provides a method for manufacturing a display panel, including the steps as follows.

At step S1, a substrate 1 is provided.

In particular, referring to FIG. 8A, the substrate 1 is a flexible material including a polyimide.

At step S2, a light-emitting layer 3 is formed on one side of the substrate 1, in which the light-emitting layer includes a plurality of light-emitting portions 31 disposed in the display area AA.

Specifically, referring to FIG. 8B, the step S2 further includes the following steps before forming the light-emitting layer 3.

At step S21, a buffer layer 21, a thin film transistor array layer 22, a planarization layer 23, an anode 24, and a pixel definition layer 4 are sequentially formed on the substrate 1.

After forming the light-emitting layer 3, the step S2 further includes the steps as follows.

At step S22, a cathode, an encapsulation layer 5, and a touch control stack 6 are sequentially formed on the pixel definition layer 4 and the light-emitting layer 3.

At step S3, a first refractive layer 7 is formed on one side of the light-emitting layer 3 which is away from the substrate 1, and the first refractive layer 7 is patterned to form a plurality of openings 71 located in the display area AA and corresponding to the light-emitting portions 31, a first groove 72 located in the non-display area NA, and a plurality of spaced-apart solid units 721 and a plurality of interconnected microgrooves 722 located in the first groove 72, in which each microgroove is disposed between every adjacent two solid units 721, and a second refractive layer 8 fills the microgrooves 722 and covers the solid units 721.

Specifically, referring to FIG. 8C, the step S3 further includes a step of forming a second groove 73 located in the non-display area NA and located on the side of the first groove 72 which is away from the display area AA, and a retaining wall 74 is provided between the first groove 72 and the second groove 73.

Specifically, the material of the first refractive layer 7 is a low refractive index material, and the microgrooves 722 and the solid units 721 are formed by the same process. Further, the microgrooves 722, the solid units 721, the first groove 72, and the second groove 73 are formed by the same process.

At step S4, a high refractive index material is printed on the side of the first refractive layer 7 which is away from the substrate 1 by an ink-jet printing process to form the second refractive layer 8, in which the microgrooves 722 are filled, and the solid units 721 are covered.

Specifically, referring to FIG. 8D, the refractive index of the second refractive layer 8 is greater than the refractive index of the first refractive layer 7. The second refractive layer 8 fills the second groove 73 and covers the retaining wall 74, or the boundary of the second refractive layer 8 is located between the second groove 73 and the first groove 72. The material of the second refractive layer 8 is an organic material, which flows and terminates between the second groove 73 and the first groove 72 when ink-jet printing is performed.

It will be appreciated that when ink-jet printing forms the second refractive layer 8, by the capillary action of the microgrooves 722, ink can flow through the channels formed by the plurality of interconnected microgrooves 722 to the edge of the first groove 72 which is close to the display area AA, thereby avoiding stress concentration in this edge position due to the fact that the edge position is not flowed by the ink, reducing the risk of wire breakage of the display panel at the time of bending, and further promoting the service life of the display panel.

An embodiment of the present application further provides a display device including the display panel in the above-described embodiment. The display device includes, but not limited to, an electronic paper, a mobile phone, a tablet computer, a television, a display, a notebook computer, a digital photo album, a GPS, and the like.

The beneficial effects are as follows. In the display panel and the display device in the embodiments of the present application, the display panel includes a substrate, a light-emitting layer, a first refractive layer, and a second refractive layer. The first refractive layer includes a first groove arranged in a display area. A plurality of spaced-apart solid units and a plurality of interconnected microgrooves are disposed in the first groove. Each microgroove is disposed between every two adjacent solid units. The second refractive layer fills the microgrooves and covers the solid units. When the second refractive layer is formed by ink-jet printing, the ink can flow through channels formed by the plurality of interconnected microgrooves to the edge of the first groove which is close to the display area by capillary action of the microgrooves, thereby avoiding the stress concentration phenomenon in this edge position due to the fact that the edge position is not flowed by the ink, reducing the risk of breaking a metal line when the display panel is bent, and prolonging the service life of the display panel.

In light of the foregoing, although the present application has been disclosed in preferred embodiments, the above preferred embodiments are not intended to limit the present application, and those of ordinary skill in the art may make various changes and modifications without departing from the spirit and scope of the present application. Therefore, the scope of protection of the present application is as defined in the claims.

1. A display panel comprising a display area and a non-display area located on at least one side of the display area;
the display panel further comprising:
a substrate;
a light-emitting layer disposed on one side of the substrate, the light-emitting layer comprising a plurality of light-emitting portions disposed in the display area;
a first refractive layer disposed on a side of the light-emitting layer which is away from the substrate, the first refractive layer comprising a plurality of openings arranged in array in the display area and corresponding to the plurality of light-emitting portions, and a first groove arranged in the non-display area; and
a second refractive layer disposed on a side of the first refractive layer which is away from the substrate, the second refractive layer filling the plurality of openings, and a refractive index of the second refractive layer being greater than a refractive index of the first refractive layer;
wherein the first groove comprises a plurality of solid units spaced apart and a plurality of interconnected microgrooves, each of the microgrooves is disposed between every adjacent two of the solid units, and the second refractive layer fills the microgrooves and covers the solid units.

2. The display panel according to claim 1, wherein the first groove comprises a plurality of groups of arrangement arrays arranged in sequence in a direction away from the display area, each of the groups of arrangement arrays comprises ones of the solid units and ones of the microgrooves arranged in sequence, the ones of the solid units in the group of arrangement arrays and the ones of the solid units in an adjacent one of the groups of arrangement arrays are staggered with respect to each other, and the ones of the microgrooves in the group of arrangement arrays and the ones of the microgrooves in the adjacent one of the groups of arrangement arrays are staggered with respect to each other.

3. The display panel according to claim 2, wherein in one column of the groups of arrangement arrays which is adjacent to the display area, sizes of ones, in the one column of the groups of arrangement arrays, of the microgrooves are gradually reduced in a direction from adjacent to the display area to away from the display area.

4. The display panel according to claim 3, wherein areas of orthographic projections of ones, in different ones of the groups of arrangement arrays, of the solid units are on the substrate are gradually reduced in the direction away from the display area.

5. The display panel according to claim 2, wherein a ratio of a distance between adjacent two of the solid units, which are each in a corresponding group of adjacent two of the groups of arrangement arrays, to a width of a bottom wall of the first groove is less than or equal to ⅛, and a ratio of a maximum dimension of each of the solid units to the width of the bottom wall of the first groove is less than or equal to ¼.

6. The display panel according to claim 5, wherein the distance between the adjacent two of the solid units, which are each in the corresponding group of the adjacent two groups of arrangement arrays, is less than or equal to 5 microns, and the maximum size of each of the solid units is less than or equal to 10 microns.

7. The display panel according to claim 5, wherein the groups of arrangement arrays comprise three or more groups of arrangement arrays.

8. The display panel according to claim 1, wherein the first groove extends through the first refractive layer, and a depth of the first groove is equal to a depth of each of the microgrooves and a height of each of the solid units in a thickness direction of the display panel.

9. The display panel according to claim 1, wherein the first refractive layer further comprises a second groove arranged within the non-display area, and the second groove is located on a side of the first groove which is away from the display area;
wherein a boundary of the second refractive layer is located in the second groove or between the second groove and the first groove.

10. The display panel according to claim 9, wherein in a thickness direction of the display panel, the microgrooves have same depths as the openings, and the first groove has a same depth as the second groove.

11. The display panel according to claim 10, wherein the non-display area comprises a bending area and a bonding area located on a side of the bending area which is away from the display area, and the bonding area is bent to a back of the display area through the bending area; wherein the first groove and the second groove are disposed between the bending area and the display area.

12. The display panel according to claim 1, wherein the display panel further comprises:
an encapsulation layer covering a side of the light-emitting layer which is away from the substrate; and
a touch control stack disposed on one side of the encapsulation layer which is away from the substrate, and the touch control stack comprises a first insulating layer, a first touch control metal layer, a second insulating layer, a second touch control metal layer, and the first refractive layer stacked in sequence, wherein the first touch control metal layer or the second touch control metal layer is provided with a touch control electrode.

13. The display panel according to claim 1, wherein a surface of one side, which is away from the substrate, of each of the solid units is provided with a plurality of micro-solid units spaced apart and a plurality of interconnected sub-microgrooves, and each of the sub-microgrooves is provided between every adjacent two of the micro-solid units.

14. A display device comprising a display panel, the display panel comprising a display area and a non-display area located on at least one side of the display area;
the display panel further comprising:
a substrate;
a light-emitting layer disposed on one side of the substrate, the light-emitting layer comprising a plurality of light-emitting portions disposed in the display area;
a first refractive layer disposed on a side of the light-emitting layer which is away from the substrate, the first refractive layer comprising a plurality of openings arranged in array in the display area and corresponding to the plurality of light-emitting portions, and a first groove arranged in the non-display area; and
a second refractive layer disposed on a side of the first refractive layer which is away from the substrate, the second refractive layer filling the plurality of openings, and a refractive index of the second refractive layer being greater than a refractive index of the first refractive layer;
wherein the first groove comprises a plurality of solid units spaced apart and a plurality of interconnected microgrooves, each of the microgrooves is disposed between every adjacent two of the solid units, and the second refractive layer fills the microgrooves and covers the solid units.

15. The display device according to claim 14, wherein the first groove comprises a plurality of groups of arrangement arrays arranged in sequence in a direction away from the display area, each of the groups of arrangement arrays comprises ones of the solid units and ones of the microgrooves arranged in sequence, the ones of the solid units in the group of arrangement arrays and the ones of the solid units in an adjacent one of the groups of arrangement arrays are staggered with respect to each other, and the ones of the microgrooves in the group of arrangement arrays and the ones of the microgrooves in the adjacent one of the groups of arrangement arrays are staggered with respect to each other.

16. The display device according to claim 15, wherein in one column of the groups of arrangement arrays which is adjacent to the display area, sizes of ones, in the one column of the groups of arrangement arrays, of the microgrooves are gradually reduced in a direction from adjacent to the display area to away from the display area.

17. The display device according to claim 16, wherein areas of orthographic projections of ones, in different ones of the groups of arrangement arrays, of the solid units are on the substrate are gradually reduced in the direction away from the display area.

18. The display device according to claim 15, wherein a ratio of a distance between adjacent two of the solid units, which are each in a corresponding group of adjacent two of the groups of arrangement arrays, to a width of a bottom wall of the first groove is less than or equal to ⅛, and a ratio of a maximum dimension of each of the solid units to the width of the bottom wall of the first groove is less than or equal to ¼.

19. The display device according to claim 18, wherein the distance between the adjacent two of the solid units, which are each in the corresponding group of the adjacent two groups of arrangement arrays, is less than or equal to 5 microns, and the maximum size of each of the solid units is less than or equal to 10 microns.

20. The display device according to claim 18, wherein the groups of arrangement arrays comprise three or more groups of arrangement arrays.
